(19) United States
(12) Patent Application Publication
(10) Pub. No.: US 2025/0347508 A1
(43) Pub. Date: Nov. 13, 2025

(54) Angle of Rotation Sensor Device and Modular Assembly System for Manufacturing an Angle of Rotation Sensor Device

(71) Applicant: HELLA GMBH & CO. KGAA, Lippstadt (DE)

(72) Inventors: Manuel Bader, Marsberg (DE); Jann Berhorst, Borchen (DE); Sascha Kuhlmann, Geseke (DE); Clemens Maßmann, Wadersloh (DE); Andreas Müller, Büren OT Siddinghausen (DE); Thomas Tegetmeyer, Paderborn (DE)

(21) Appl. No.: 19/198,602

(22) Filed: May 5, 2025

(30) Foreign Application Priority Data
May 7, 2024 (DE) 102024112734.1

(51) Int. Cl. G01B 7/30; H05K 1/14

(52) U.S. Cl. CPC G01B 7/30; H05K 1/144; H05K 1/145; H05K 2201/042

(57) ABSTRACT

The present invention relates to an angle of rotation sensor device. The sensor device includes: a carrier assembly with a carrier assembly base body which forms a rotor chamber, a rotor assembly which is arranged rotatably relative to the carrier assembly in the rotor chamber, and first and second circuit board assemblies respectively attached to the carrier assembly. The first circuit board assembly includes a detection apparatus which interacts with the rotatable rotor assembly to detect an angle of rotation. The second circuit board assembly includes a connector contact apparatus, and the carrier assembly includes a connecting apparatus which is attached to the carrier assembly base body and establishes an electrical connection between the first circuit board assembly and the second circuit board assembly. The present invention further relates to a modular assembly system for manufacturing such an angle of rotation sensor device.

### CROSS-REFERENCE TO RELATED APPLICATIONS

The present application claims the benefit of German Patent Application No. 10-10-2024-112-734.1, filed May 7, 2024, the disclosure of which is incorporated by reference.

### BACKGROUND OF THE INVENTION

The present invention relates to an angle of rotation sensor device and a modular assembly system for manufacturing an angle of rotation sensor device.

DE 200 08 200 U1 discloses an assembly system for manufacturing a rotary encoder device that comprises a selection of different printed circuit board assemblies with different drivers and interfaces.

### SUMMARY OF THE INVENTION

The present invention is based on the object of realizing an angle of rotation sensor device that can be easily adapted for different applications.

According to the invention, this object is achieved by an angle of rotation sensor device with the features of the current embodiments and by a modular assembly system for manufacturing an angle of rotation sensor device with the features of the current embodiments.

In the following, an assembly is to be understood as a unit consisting of a plurality of individual parts that are firmly connected to one another, which are provided pre-assembled or prefabricated during assembly and installed as a whole. In this context, an assembly is also explicitly understood to be a unit that cannot be dismantled non-destructively.

The angle of rotation sensor device according to the invention comprises at least one carrier assembly, one rotor assembly and two printed circuit board assemblies.

The carrier assembly comprises a carrier assembly base body consisting of one or more parts, which forms a preferably substantially cylindrical rotor chamber in which the rotor assembly is arranged. The carrier assembly further comprises a connecting apparatus which is attached to the carrier assembly base body and provides an electrical connection between the two printed circuit board assemblies.

The connecting apparatus typically comprises a plurality of connecting elements made of an electrically conductive material, preferably a metal, which are electrically insulated from one another. The connecting elements are preferably embedded in the carrier assembly base body, for example inserted into corresponding openings in the carrier assembly base body or encapsulated by the carrier assembly base body, but can in principle also be attached to an outer surface of the carrier assembly base body. In any case, the connecting elements are firmly connected to the carrier assembly base body. Preferably, the connecting elements are designed to be pin-shaped and extend through the carrier assembly base body. In principle, however, the connecting elements can be designed in any way suitable for establishing an electrical connection between the two printed circuit board assemblies, for example as contact surfaces that are contacted by spring contacts of the printed circuit board assemblies.

The rotor assembly is preferably designed to substantially be of a circular disc-shape and, depending on the sensor technology used, has different characteristic features that enable the angle of rotation of the rotor assembly to be detected by a suitably designed detection apparatus of the first printed circuit board assembly. In the case of contactless inductive sensor technology, the rotor assembly has, for example, a short-circuit winding formed in a known manner, which is typically arranged on a side of a substantially circular disk-shaped rotor assembly base body made of an electrically insulating material, preferably a plastic, facing the first printed circuit board. The short-circuit winding is preferably rotationally symmetrical in relation to an axis of rotation of the rotor assembly and preferably runs in a meandering manner around the axis of rotation. In the case of magnet-based sensor technology, however, the rotor assembly has one or more permanent magnets that generate a defined sequence of at least one magnetic north pole and at least one magnetic south pole in a known manner along a circumferential direction of the rotor assembly. On a side facing away from the first printed circuit board assembly, the rotor assembly preferably has a coupling apparatus for rotationally fixed coupling of the rotor assembly to a shaft or another rotatable body whose angle of rotation is to be detected by the angle of rotation sensor device according to the invention.

The first printed circuit board arrangement comprises a first printed circuit board which is attached to the carrier assembly, in particular to the carrier assembly base body, and on which the components of the detection apparatus which interacts with the rotor assembly to detect the angle of rotation of the rotor assembly are arranged. The first printed circuit board is preferably arranged substantially perpendicular to the axis of rotation of the rotor assembly. Preferably, the first printed circuit board completely covers the side of the carrier assembly base body on which the first printed circuit board is arranged and preferably does not protrude significantly laterally beyond the carrier assembly base body.

Depending on the sensor technology used, the detection apparatus of the first printed circuit board assembly has different characteristic features. In the case of contactless inductive sensor technology, the detection apparatus has, for example, at least one transmitter coil running around the axis of rotation of the rotor assembly, a plurality of receiver coils distributed along a circumferential direction running around the axis of rotation of the rotor assembly and electronics which are configured to impress an alternating current into the transmitter coil and to detect a voltage induced in the individual receiver coils. In the case of magnet-based sensor technology, however, the detection apparatus comprises one or more magnetic field sensors, preferably one or more Hall sensors, for detecting the magnetic field generated by the at least one permanent magnet of the rotor assembly.

The first printed circuit board assembly further comprises a first connecting contact apparatus electrically contacted by the connecting apparatus of the carrier assembly, wherein the first connecting contact apparatus comprises a plurality of connecting contacts made of an electrically conductive material, each of which is in direct physical contact with one of the connecting elements of the connecting apparatus. Preferably, the connecting contacts of the first connecting contact apparatus are designed as receptacles which are designed to corresponding to the connecting elements of the connecting apparatus and into each of which one of the connecting elements of the connecting apparatus engages.

The second printed circuit board assembly comprises a second printed circuit board which is attached to the carrier assembly, in particular to the carrier assembly base body, and on which a connector contact apparatus for connecting the angle of rotation sensor device according to the invention to an external system is arranged. The second circuit board is preferably arranged substantially perpendicular to the axis of rotation of the rotor assembly. Preferably, the second printed circuit board has a section protruding laterally beyond the carrier assembly, with the connector contact apparatus being arranged on the protruding section of the second printed circuit board. The second printed circuit board preferably completely covers the side of the carrier assembly base body on which the second printed circuit board is arranged and, apart from the protruding section of the second printed circuit board, preferably does not protrude significantly laterally beyond the carrier assembly base body.

The connector contact apparatus comprises a plurality of connector contacts made of an electrically conductive material, which are arranged, preferably next to one another, on a surface of the second printed circuit board. The connector contacts are arranged at a defined distance from each other, wherein the distance between two neighboring connector contacts is also referred to as “pitch”. Preferably, the connector contacts are designed as contact surfaces. A connector plug is preferably connected to the connector contact apparatus, wherein plug contacts of the connector plug are each electrically connected to one of the connector contacts of the connector contact apparatus. The connector contact apparatus is typically used to supply electrical energy from the external system to the angle of rotation sensor device according to the invention. Furthermore, the connector contact apparatus typically forms a data interface for data transmission between the angle of rotation sensor device according to the invention and the external system, wherein the data interface can in principle be based on different interface standards such as SENT, PSI5 or CAN or can also be adapted to transmit defined analog signals or defined pulse-width modulated signals.

The second circuit board assembly further comprises a second connecting contact apparatus electrically contacted by the connecting apparatus of the carrier assembly, the second connecting contact apparatus having a plurality of connecting contacts made of an electrically conductive material, each of which is in direct physical contact with one of the connecting elements of the connecting apparatus. Preferably, the connecting contacts of the second connecting contact apparatus are designed-analogous to the connecting contacts of the first connecting contact apparatus—as receptacles which are designed to correspond to the connecting elements of the connecting apparatus and into each of which one of the connecting elements of the connecting apparatus engages.

The angle of rotation sensor device according to the invention can be easily adapted for different applications by using differently configured rotor assemblies, differently configured first printed circuit board assemblies and/or differently configured second printed circuit board assemblies.

Preferably, the carrier assembly comprises a one-piece carrier assembly base body to which the connecting apparatus is attached. Preferably, the carrier assembly base body is a solid body manufactured by means of a casting process. This creates a carrier assembly that is relatively easy to manufacture.

Preferably, the carrier assembly base body consists of an electrically insulating plastic, wherein the carrier assembly base body is preferably manufactured by means of an injection molding process. This creates a carrier assembly that is relatively easy to manufacture. Particularly preferably, the connecting elements of the connecting apparatus are overmolded by the carrier assembly base body and thus reliably attached to the carrier assembly base body.

In a preferred embodiment, the carrier assembly, in particular the carrier assembly base body, comprises a wall which is arranged between the rotor assembly and the first printed circuit board assembly and prevents the first printed circuit board assembly and the rotor assembly from touching one another. Furthermore, the wall, in particular the wall thickness of the wall, can be used to easily determine a defined distance between the rotor assembly and the detection apparatus which is arranged on the first printed circuit board of the first printed circuit board assembly and interacts with the rotor assembly to detect the angle of rotation.

Preferably, the carrier assembly comprises a snap apparatus by means of which the rotor assembly is held in the rotor chamber. This enables easy installation of the rotor assembly in the rotor chamber of the carrier assembly. Preferably, the snap apparatus comprises a plurality of snap elements, preferably so-called snap hooks, arranged distributed along a circumference of the rotor assembly, which grip around an edge of the rotor assembly. Preferably, the snap elements of the snap apparatus are formed in one piece with the carrier assembly base body. In principle, however, the rotor assembly can also be held in the rotor chamber in any other way, for example by means of a bayonet apparatus.

In a preferred embodiment, the connecting apparatus comprises connecting elements protruding from the carrier assembly and the first printed circuit board assembly and the second printed circuit board assembly each have receptacles which are designed to corresponding to the connecting elements and into which the connecting elements engage. Preferably, the protruding areas of the connecting elements are each designed as spring plugs or lamellar plugs in order to realize a reliable electrical contact with the respective receptacle of the printed circuit board assembly. Preferably, the receptacles of the two printed circuit board assemblies are designed as through-openings of the first printed circuit board or the second printed circuit board, through which the protruding area of the corresponding connecting element extends.

Preferably, the first printed circuit board assembly and/or the second printed circuit board assembly are attached to the carrier assembly via the connecting apparatus. This allows for easy mounting of the first printed circuit board assembly and/or the second printed circuit board assembly on the carrier assembly. Here, the attachment can be realized, for example, by connecting elements of the connecting apparatus designed as spring plugs or lamellar plugs, wherein the plugs are inserted into corresponding through-openings of the first printed circuit board or the second printed circuit board, and wherein the plugs are each designed such that the respective printed circuit board is held on the carrier assembly by the spring force exerted on the respective printed circuit board by the spring or the lamellae of the plug. In this way, a reliable and detachable attachment of the first printed circuit board assembly and/or the second printed circuit board assembly to the carrier assembly can be realized in a simple manner, wherein the respective printed circuit board assembly can be mounted on the carrier assembly in a simple manner by sliding it onto the connecting elements.

In a preferred embodiment, the first printed circuit board assembly and the second printed circuit board assembly are arranged on opposite sides of the carrier assembly so that the two printed circuit board assemblies can be connected to one another in a simple manner by means of straight connecting elements extending through the carrier assembly base body.

Preferably, the first printed circuit board assembly and/or the second printed circuit board assembly are designed and arranged such that an open side of the rotor chamber is at least partially covered by the first printed circuit board assembly and/or by the second printed circuit board assembly, so that the rotor assembly is prevented from falling out of the rotor chamber by the first printed circuit board assembly and/or by the second printed circuit board assembly, without additional means having to be provided for this purpose. Preferably, the first printed circuit board assembly or the second printed circuit board assembly substantially completely covers the respective open side of the rotor chamber, wherein the second printed circuit board of the second printed circuit board assembly typically has a through-opening via which a coupling element can be inserted into the coupling apparatus of the rotor assembly for non-rotational coupling of the rotor assembly.

Preferably, the first printed circuit board assembly comprises evaluation electronics which are designed in a known manner to determine digital sensor data indicating an angle of rotation based on a generally analog measurement signal provided by the detection apparatus. Typically, the evaluation electronics comprise a microcontroller, a so-called ASIC or a so-called FPGA as well as an analog-to-digital converter, wherein the analog-to-digital converter can also be integrated into one of the aforementioned components.

In a preferred embodiment, the first printed circuit board assembly or the second printed circuit board assembly comprises a voltage regulating apparatus which is electrically connected to the connector contact apparatus and which is arranged to provide a defined, regulated supply voltage for operating electrical and/or electronic components of the first printed circuit board assembly and/or the second printed circuit board assembly. The voltage regulation apparatus can, for example, be configured to provide a regulated supply voltage of 5 V, 12 V or 24 V. Preferably, the voltage regulating apparatus also comprises one or more protective circuits, for example for protection against electrostatic discharge and/or for protection against electromagnetic radiation.

Preferably, the first printed circuit board assembly or the second printed circuit board assembly comprises a further detection apparatus which interacts with the rotatable rotor assembly for detecting the angle of rotation, wherein the further detection apparatus is preferably based on a different sensor technology than the detection apparatus described above. The further detection apparatus enables particularly reliable detection of the angle of rotation.

The modular assembly system according to the invention for manufacturing an angle of rotation sensor device according to the invention described above comprises the assemblies described above, i.e. the carrier assembly, the rotor assembly, the first printed circuit board assembly and the second printed circuit board assembly, wherein according to the invention at least one of the following assemblies is present in a plurality of different configurations: the rotor assembly, the first printed circuit board assembly and the second printed circuit board assembly, wherein each of the different configurations is adapted to be mounted on the carrier assembly. Preferably, each of the aforementioned assemblies is present in a plurality of different configurations.

The rotor assembly and the first printed circuit board assembly can, for example, each be present in a plurality of configurations that are adapted for different angle of rotation measuring ranges and/or that are based on different sensor technologies. The first printed circuit board assembly and the second printed circuit board assembly further can, for example, each be present in a plurality of configurations which are adapted for different data interfaces and/or different supply voltages and/or which differ in terms of the components present, for example with/without further detection apparatus. Furthermore, it is also conceivable, for example, that the second printed circuit board assembly is present in a plurality of configurations that differ in terms of distance, number and/or position of the connector contacts of the connector contact apparatus in order to enable the connection of different connector plugs.

The modular assembly system according to the invention makes it possible to easily manufacture an angle of rotation sensor device adapted to different applications by selecting different configurations of the individual assemblies.

### BRIEF DESCRIPTION OF THE DRAWINGS

An exemplary embodiment of the present invention is described below with reference to the accompanying figures. In the figures:

FIG. 1 schematically shows an angle of rotation sensor device according to an embodiment of the invention;

FIG. 2 schematically shows the angle of rotation sensor device from FIG. 1, but without a first printed circuit board assembly;

FIG. 3 schematically shows a rotor assembly and a carrier assembly of the angle of rotation sensor device from FIG. 1;

FIG. 4 schematically shows a top face of the rotor assembly that is not visible in FIG. 3; and

FIG. 5 schematically shows different configurations of the rotor assembly present in a modular assembly system according to an embodiment of the invention for manufacturing an angle of rotation sensor device.

### DETAILED DESCRIPTION OF THE CURRENT EMBODIMENT

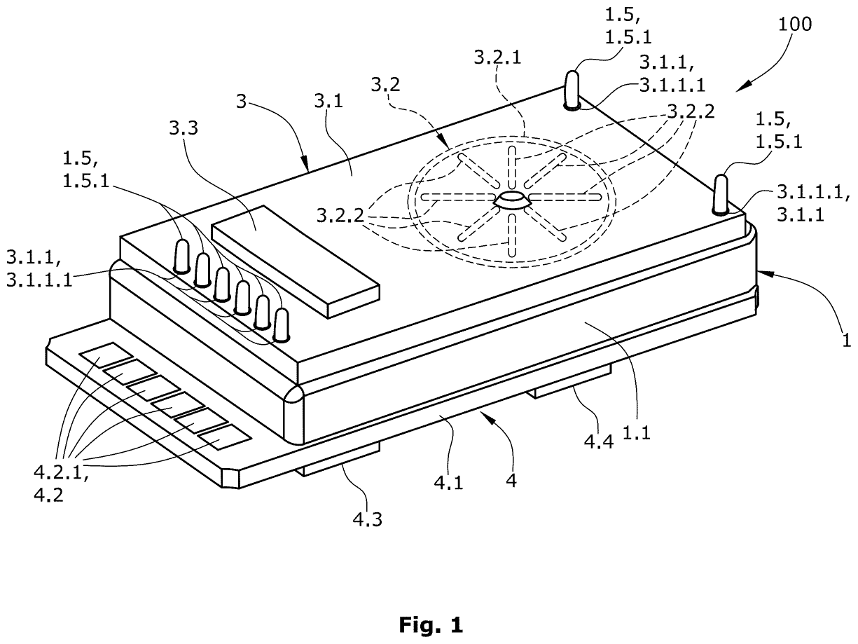

FIG. 1 shows an angle of rotation sensor device 100 according to the invention with a carrier assembly 1, a rotor assembly 2, a first printed circuit board assembly 3 and a second printed circuit board assembly 4, wherein the angle of rotation sensor device 100 is based on the so-called contactless inductive sensor technology in the present exemplary embodiment.

The carrier assembly 1 comprises a one-piece carrier assembly base body 1.1 made of a plastic and manufactured by means of an injection molding process.

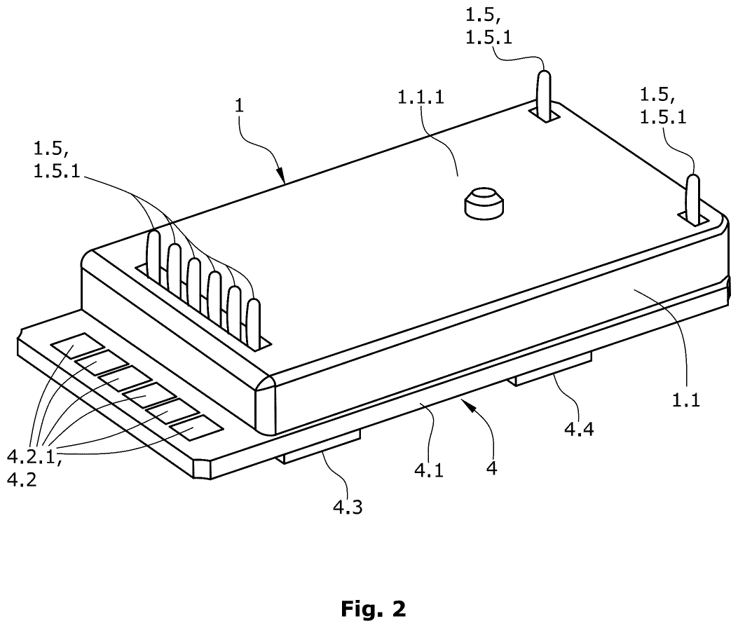

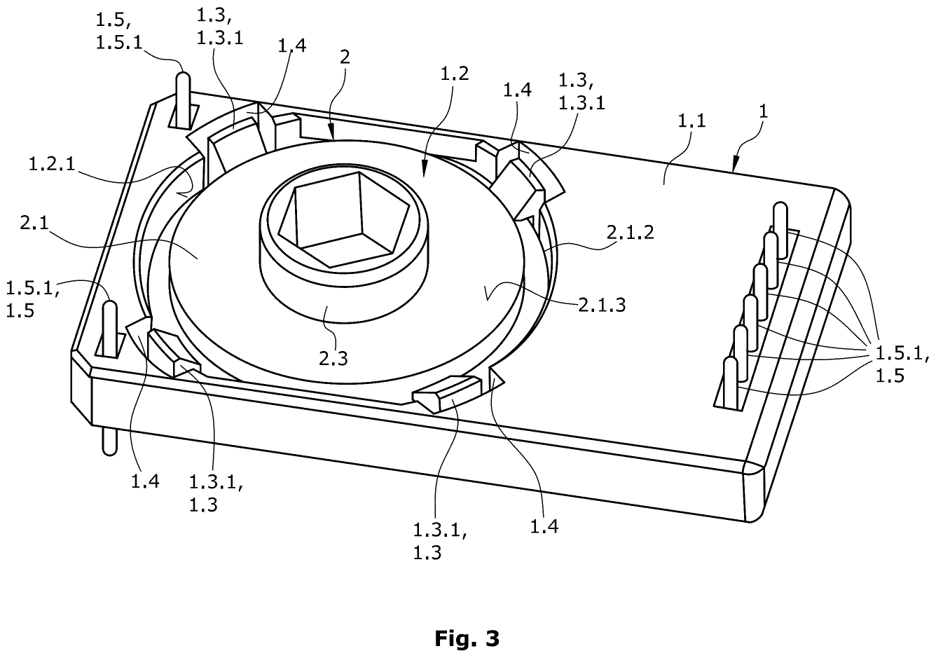

A substantially cylindrical rotor chamber 1.2 is formed in the carrier assembly base body 1.1, which is open on a bottom face shown in FIG. 3 and is bounded on a top face by a top wall 1.1.1 shown in FIG. 2, which is formed by the carrier assembly base body 1.1.

The carrier assembly 1 comprises a snap apparatus 1.3 with four snap elements 1.3.1, which are formed in one piece with the carrier assembly base body 1.1 and are arranged in pockets 1.4 formed in a circumferential wall 1.2.1 of the rotor chamber 1.2 and engage around an edge 2.1.2 of a rotor assembly base body 2.1 of the rotor assembly 2.

The carrier assembly 1 comprises a connecting apparatus 1.5 with eight pin-shaped connecting elements 1.5.1 made of a metal, which are overmolded by the carrier assembly base body 1.1 and thus attached to the carrier assembly base body 1.1.

The connecting elements 1.5 protrude from the carrier assembly base body 1.1 both on the top face shown in FIG. 2 and on the bottom face shown in FIG. 3, wherein the protruding areas of the connecting elements 1.5.1 are each designed as spring plugs or lamellar plugs.

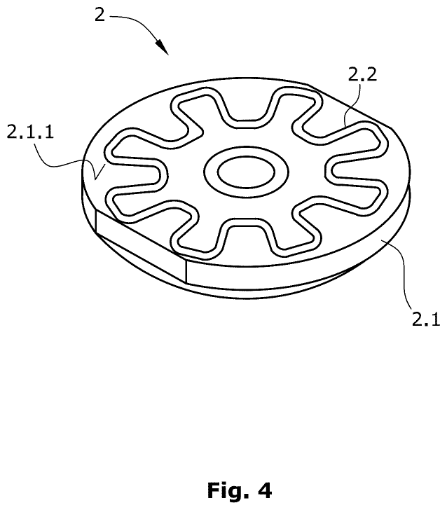

The rotor assembly 2 comprises the rotor assembly base body 2.1, which is made of a plastic and on the top face 2.1.1 of which, shown in FIG. 4, a short-circuit winding 2.2 which is designed in a meandering shape running around an axis of rotation of the rotor assembly 2 is arranged.

On a bottom face 2.1.3 of the rotor assembly base body 2.1 shown in FIG. 3, a coupling apparatus 2.3 is formed for rotationally fixed coupling of the rotor assembly 2 with a shaft or another rotatable body whose angle of rotation is to be detected.

The rotor assembly 2 is arranged in the rotor chamber 1.2 with the top face 2.1.1 of the rotor assembly base body 2.1 pointing in the direction of the top wall 1.1.1 of the carrier assembly base body 1.1, wherein the rotor assembly 2 is rotatably mounted relative to the carrier assembly 1 and is held in the rotor chamber 1.2 by the snap apparatus 1.3.

The first printed circuit board assembly 3 comprises a first printed circuit board 3.1, which rests against an outer side of the top wall 1.1.1 of the carrier assembly base body 1.1 facing away from the rotor chamber 1.2.

The first printed circuit board 3.1 comprises a first connecting contact apparatus 3.1.1 with eight receptacles 3.1.1.1, which are designed and arranged to correspond to the connecting elements 1.5 and into each of which one of the connecting elements 1.5 engages, thereby both electrically contacting the first printed circuit board 3.1 and attaching it to the carrier assembly base body 1.1.

On a bottom face of the first printed circuit board 3.1, which is not visible in FIG. 1, a detection apparatus 3.2 is arranged, which is indicated by a dashed line in FIG. 1 and which comprises a transmitter coil 3.2.1 and a plurality of receiver coils 3.2.2, and which interacts in a known manner with the short-circuit winding 2.2 of the rotor assembly 2 to detect an angle of rotation of the rotor assembly 2 relative to the carrier assembly 1.

The first printed circuit board assembly 3 further comprises evaluation electronics 3.3, which is designed in a known manner to determine sensor data indicating the angle of rotation of the rotor assembly 2 relative to the carrier assembly 1 based on a measurement signal provided by the detection apparatus 3.2.

The second printed circuit board assembly 4 comprises a second printed circuit board 4.1, which rests against the bottom face of the carrier assembly base body 1.1 shown in FIG. 3 and covers the open side of the rotor chamber 1.2, so that the second printed circuit board 4.1 prevents the rotor assembly 2 from falling out of the rotor chamber 1.2.

The second printed circuit board 4.1 comprises a second connecting contact apparatus, not shown here, designed analogously to the first connecting contact device 3.1.1 of the first printed circuit apparatus 3.1, in the eight receptacles of which one of the connecting elements 1.5 also engages, thereby both electrically contacting the second printed circuit board 4.1 and attaching it to the carrier module base body 1.1.

The second printed circuit board 4.1 is therefore electrically connected to the first printed circuit board 3.1 via the connecting elements 1.5.

The second printed circuit board 4.1 further comprises a through-opening, also not shown here, via which a coupling element for rotationally fixed coupling of the rotor assembly 2 with the shaft or the rotatable body whose angle of rotation is to be detected can be inserted into the coupling apparatus 2.3 of the rotor assembly 2.

The second printed circuit board assembly 4 further comprises a connector contact apparatus 4.2 arranged on the second printed circuit board 4.1 with six connector contacts 4.2.1 made of a metal for connecting the angle of rotation sensor device 100 to an external system not shown here.

A connector plug not shown is arranged on the connector contact apparatus 4.2, the plug contacts of which are each electrically connected to one of the connector contacts 4.2.1, which is why the connector contacts 4.2.1 are positioned corresponding to the positions of the plug contacts of the respective connector plug.

On the one hand, the connector contact apparatus 4.2 is used to supply electrical energy from the external system to the angle of rotation sensor device 100, and on the other hand, the connector contact apparatus 4.2 forms a data interface for data transmission between the angle of rotation sensor device 100 and the external system.

The second printed circuit board assembly 4 further comprises a voltage regulating apparatus 4.3, which is electrically connected to the connector contact apparatus 4.2 and to which electrical energy is supplied from the external system via the connector contact apparatus 4.2.

Here, the voltage regulating apparatus 4.3 is configured up in a known manner to provide a defined supply voltage to the evaluation electronics 3.3 and to the other electrical and electronic components of the first printed circuit board arrangement 3 and the second printed circuit board arrangement 4.

The second printed circuit board assembly 4 further comprises a further detection apparatus 4.4, for example a magnet-based detection apparatus, which interacts with the rotor assembly 2, for example with a permanent magnet of the rotor assembly not shown here, in order to detect the angle of rotation of the rotor assembly 2 relative to the carrier assembly 1.

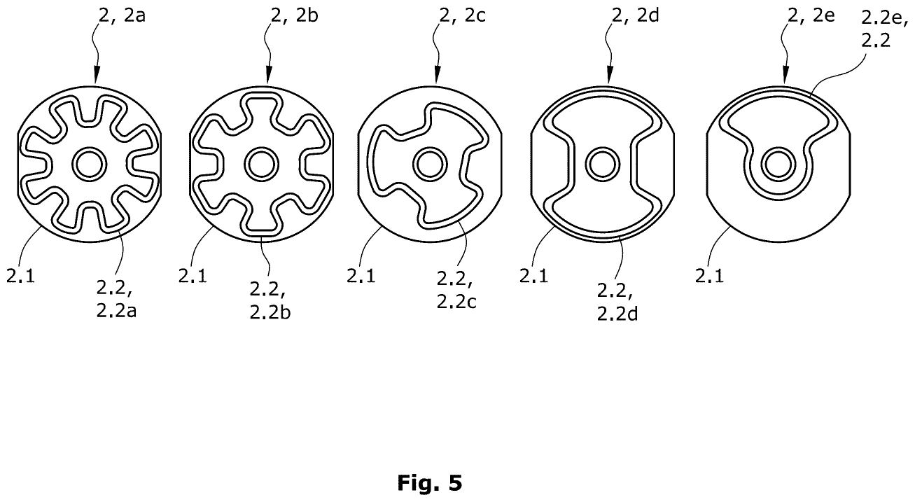

FIG. 5 shows, by way of example, five different configurations 2a-2e of the rotor assembly 2 present in a modular assembly system according to the invention for manufacturing the angle of rotation sensor device 100.

The individual configurations 2a-2e of the rotor assembly 2 are adapted for different angle of rotation measuring ranges, which is expressed by different configurations 2.2a-2.2e of the short-circuit winding 2.2 of the rotor assembly 2.

However, all configurations 2a-2e of the rotor assembly 2 have a substantially identical rotor assembly base body 2.1, so that all configurations 2a-2e of the rotor assembly 2 can be mounted in the rotor chamber 1.2 of the carrier assembly 1.

In principle, it is also conceivable that the modular assembly system according to the invention, in addition to or as

an alternative to the different configurations 2a-2e of the rotor assembly 2, comprises other configurations of the rotor assembly 2, different configurations of the first printed circuit board assembly 3 and/or different configurations of the second printed circuit board assembly 4.

The rotor assembly 2 and the first printed circuit board assembly 3 can, for example, each be present in a plurality of configurations based on different sensor technologies.

Furthermore, the first printed circuit board assembly 3 and the second printed circuit board assembly 4 can, for example, each be present in a plurality of configurations adapted for different data interfaces and/or different supply voltages.

Furthermore, it is also conceivable, for example, that the second printed circuit board assembly 4 is present in a plurality of configurations that differ in terms of distance, number and/or position of the connector contacts 4.2.1 of the connector contact apparatus 4.2 in order to enable the connection of different connector plugs.

Furthermore, it is also conceivable that the second printed circuit board assembly 4 is present in a configuration with the further detection apparatus 4.4 and in a configuration without the further detection apparatus 4.4.

In principle, it is also conceivable that both the first printed circuit board assembly 3 and the second printed circuit board assembly 4 are present in a plurality of configurations that differ in terms of the electrical and/or electronic components present and/or their design.

In summary, the invention relates to an angle of rotation sensor device 100 comprising: a carrier assembly 1 with a carrier assembly base body 1.1 which forms a rotor chamber 1.2, a rotor assembly (2) which is arranged rotatably relative to the carrier assembly (1) in the rotor chamber (1.2), a first circuit board assembly 3 which is attached to the carrier assembly 1, and a second circuit board assembly 4 which is attached to the carrier assembly (1), wherein the first circuit board assembly 3 comprises a detection apparatus 3.2 which interacts with the rotatable rotor assembly 2 to detect an angle of rotation, wherein the second printed circuit board assembly 4 comprises a connector contact apparatus 4.2 for connection to an external system, and wherein the carrier assembly 1 comprises a connecting apparatus 1.5 which is attached to the carrier assembly base body 1.1 and establishes an electrical connection between the first printed circuit board assembly 3 and the second printed circuit board assembly 4. The present invention further relates to a modular assembly system for manufacturing such an angle of rotation sensor device 100, wherein at least one of the following assemblies is provided in a plurality of different configurations 2a-2e: the rotor assembly 2, the first circuit board assembly 3 and the second circuit board assembly 4, wherein each of the different configurations 2a-2e is adapted to be mounted to the carrier assembly 1.

### LIST OF REFERENCE NUMBERS

100 angle of rotation sensor device
1 carrier assembly
1.1 carrier module base body
1.1.1 top wall
1.2 rotor chamber
1.2.1 circumferential wall
1.3 snap apparatus
1.3.1 snap elements
1.4 pockets
1.5 connecting apparatus
1.5.1 connecting elements
2 rotor assembly
2a-2e configurations of the rotor assembly
2.1 rotor assembly base body
2.1.1 top face
2.1.2 edge
2.1.3 bottom face
2.2 short-circuit winding
2.2a-2.2e configurations of the short-circuit winding
2.3 coupling apparatus
3 first printed circuit board assembly
3.1 first printed circuit board
3.1.1 first connecting contact apparatus
3.1.1.1 receptacle
3.2 detection apparatus
3.2.1 transmitter coil
3.2.2 receiver coils
3.3 evaluation electronics
4 second printed circuit board assembly
4.1 second circuit board
4.2 connector contact apparatus
4.2.1 connector contacts
4.3 voltage regulation apparatus
4.4 further detection apparatus

The above description is that of current embodiment of the invention. Various alterations and changes can be made without departing from the spirit and broader aspects of the invention. This disclosure is presented for illustrative purposes and should not be interpreted as an exhaustive description of all embodiments of the invention or to limit the scope of the claims to the specific elements illustrated or described in connection with these embodiments. Any reference to elements in the singular, for example, using the articles “a,” “an,” “the,” or “said,” is not to be construed as limiting the element to the singular.

1. An angle of rotation sensor device, comprising:
a carrier assembly with a carrier assembly base body forming a rotor chamber;
a rotor assembly which is arranged rotatably relative to the carrier assembly in the rotor chamber;
a first printed circuit board assembly attached to the carrier assembly; and
a second printed circuit board assembly attached to the carrier assembly,
wherein the first printed circuit board assembly comprises a detection apparatus which interacts with the rotatable rotor assembly to detect the angle of rotation,
wherein the second printed circuit board assembly comprises a connector contact apparatus for connecting to an external system, and
wherein the carrier assembly comprises a connecting apparatus which is attached to the carrier assembly base body and establishes an electrical connection between the first printed circuit board assembly and the second printed circuit board assembly.

2. The angle of rotation sensor device according to claim 1, wherein the carrier assembly base body is formed in one piece.

3. The angle of rotation sensor device according to claim 2, wherein the carrier assembly base body is made of a plastic.

4. The angle of rotation sensor device according to claim 1, wherein the carrier assembly comprises a wall arranged between the rotor assembly and the first printed circuit board assembly.

5. The angle of rotation sensor device according to claim 1, wherein the carrier assembly comprises a snap apparatus by which the rotor assembly is held in the rotor chamber.

6. The angle of rotation sensor device according to claim 1, wherein the connecting apparatus of the carrier assembly base body comprises protruding connecting elements, and wherein the first printed circuit board assembly and the second printed circuit board assembly each have receptacles which are designed to correspond to the connecting elements and in which the connecting elements engage.

7. The angle of rotation sensor device according to claim 1, wherein the first printed circuit board assembly or the second printed circuit board assembly are attached to the carrier assembly via the connecting apparatus.

8. The angle of rotation sensor device according to claim 1, wherein the first printed circuit board assembly and the second printed circuit board assembly are arranged on opposite sides of the carrier assembly.

9. The angle of rotation sensor device according to claim 1, wherein the first printed circuit board assembly or the second printed circuit board assembly are designed and arranged such that the rotor assembly is prevented from falling out of the rotor chamber by the first printed circuit board assembly or by the second printed circuit board assembly.

10. The angle of rotation sensor device according to claim 1, wherein the first printed circuit board assembly comprises evaluation electronics which are designed to determine sensor data indicating an angle of rotation based on a measurement signal provided by the detection apparatus.

11. The angle of rotation sensor device according to claim 1, wherein the first printed circuit board assembly or the second printed circuit board assembly comprises a voltage regulating apparatus which is electrically connected to the connector contact apparatus and which is arranged to provide a defined supply voltage.

12. The angle of rotation sensor device according to claim 1, wherein the first printed circuit board assembly or the second printed circuit board assembly comprises a further detection apparatus which interacts with the rotatable rotor assembly for detecting the angle of rotation.

13. A modular assembly system for manufacturing an angle of rotation sensor device according to claim 1, wherein at least one of the following assemblies is present in a plurality of different configurations: the rotor assembly, the first printed circuit board assembly and the second printed circuit board assembly, wherein each of the different configurations is adapted to be mounted to the carrier assembly.
